(19) United States
(12) Patent Application Publication
(10) Pub. No.: US 2026/0182050 A1
(43) Pub. Date: Jun. 25, 2026

(54) PHOTOTRANSISTOR

(71) Applicant: Taiwan-Asia Semiconductor Corporation, Hsinchu City (TW)

(72) Inventors: Cheng-Chang Wei, Hsinchu City (TW); Hou-Jun Wu, Hsinchu City (TW)

(21) Appl. No.: 19/278,040

(22) Filed: Jul. 23, 2025

(30) Foreign Application Priority Data
Dec. 19, 2024 (TW) 113149544

(51) Int. Cl. H10F 30/24

(52) U.S. Cl. CPC H10F 30/245

(57) ABSTRACT

A phototransistor is provided. The phototransistor comprises a first conductivity-type substrate, a second conductivity-type base region, and a first conductivity-type patterned emitter region. The second conductivity-type base region is disposed within the first conductivity-type substrate. The first conductivity-type patterned emitter region includes multiple emitter sub-regions, each independently located within the second conductivity-type base region to increase electron injection pathways.

### CROSS-REFERENCES TO RELATED APPLICATIONS

This application claims the benefit of priority to Taiwanese Patent Application No. 113149544 filed on Dec. 19, 2024, which is hereby incorporated by reference in its entirety.

### BACKGROUND OF THE INVENTION

### Field of the Invention

This invention relates to a phototransistor, and in particular to a phototransistor capable of increasing current gain.

### Descriptions of the Related Art

A phototransistor is a semiconductor device capable of converting optical signals into electrical signals. It is similar to a conventional Bipolar Junction Transistor (BJT), where the base can be controlled not only by an electrical current signal but also by an optical signal. Phototransistors are commonly used in photodetection applications, such as optical couplers and photodetectors.

The basic structure of a phototransistor is similar to that of a conventional bipolar junction transistor, typically comprising an NPN or PNP structure. Please refer to FIG. 1 and FIG. 2, which illustrate a conventional NPN phototransistor 1 comprising a substrate 10, a base region 20, an emitter region 30, an emitter electrode 40, and a collector electrode 50. FIG. 2 is a cross-sectional schematic view along the AA line segment of FIG. 1. When light irradiates the base region 20 of the phototransistor, photons excite electrons, generating electron-hole pairs. These electrons and holes are separated under the influence of an electric field, forming a base-collector current (I_{BC}). Due to the electron flow in the base region, the generated electrons primarily flow toward the emitter region 30, resulting in an increase in the emitter-collector current (I_{EC}). The I_{EC} is typically larger than the I_{BC} because most photo-generated electrons flow out through the emitter region 30, which is the gain effect of the phototransistor. The relationship between I_{EC} and I_{BC} is given by I_{EC}=β×I_{BC}, where β is the current gain (hFE) of the phototransistor, with a value greater than 1, typically ranging from tens to hundreds.

As shown in FIG. 3, the peripheral contour of the emitter region 30 in the conventional phototransistor 1 typically has a simple circular, square, or polygonal shape. Such emitter region designs result in limited current gain, failing to meet the demands of next-generation optoelectronic devices for higher photocurrent gain, higher breakdown voltage, and lower leakage current. Therefore, there is an urgent need in the industry for an innovative phototransistor structure to meet the high-performance requirements of next-generation phototransistors.

### SUMMARY OF THE INVENTION

The main objective of this invention is to provide an innovative phototransistor that increases photocurrent gain, enhances voltage withstand capability, and reduces device leakage current, thereby improving device performance.

To achieve the above objective, this invention provides a phototransistor comprising a first conductivity-type substrate, a second conductivity-type base region, and a first conductivity-type patterned emitter region. The second conductivity-type base region is disposed within the first conductivity-type substrate. The first conductivity-type patterned emitter region includes a plurality of emitter sub-regions, each independently disposed within the second conductivity-type base region to increase electron injection pathways.

In one embodiment of the phototransistor of this invention, each emitter sub-region of the first conductivity-type patterned emitter region is arranged in a grid pattern, distributed within the second conductivity-type base region.

In one embodiment of the phototransistor of this invention, each emitter sub-region of the first conductivity-type patterned emitter region is arranged in a mesh pattern, distributed within the second conductivity-type base region.

In one embodiment of the phototransistor of this invention, the phototransistor further comprises an emitter electrode electrically connected to the first conductivity-type patterned emitter region.

In one embodiment of the phototransistor of this invention, the emitter electrode comprises an extension portion and an outer ring portion, the outer ring portion being disposed on an edge of the second conductivity-type base region, and the extension portion extending from the outer ring portion to the first conductivity-type patterned emitter region, electrically connecting to each emitter sub-region of the first conductivity-type patterned emitter region.

In one embodiment of the phototransistor of this invention, the extension portion has a hollow annular shape, disposed on an edge of the first conductivity-type patterned emitter region.

In one embodiment of the phototransistor of this invention, the first conductivity-type substrate serves as a collector.

In one embodiment of the phototransistor of this invention, the phototransistor further comprises a collector electrode disposed on one side of the first conductivity-type substrate.

In one embodiment of the phototransistor of this invention, a width (W_{E}) of each emitter sub-region is greater than 20 micrometers (μm).

In one embodiment of the phototransistor of this invention, a width (W_{B}) of the second conductivity-type base region between adjacent emitter sub-regions is greater than 6 micrometers (μm).

In one embodiment of the phototransistor of this invention, the ratio of the area of the second conductivity-type base region to the total area of the first conductivity-type patterned emitter region is not less than 0.09.

To achieve the above objective, this invention provides a phototransistor comprising a substrate, a base region, and a patterned emitter region. The base region is disposed within the substrate. The patterned emitter region forms a plurality of discontinuous PN junctions with the base region to increase electron injection pathways.

In another embodiment of the phototransistor of this invention, the discontinuous PN junctions of the patterned emitter region are arranged in a grid pattern, distributed within the base region.

In another embodiment of the phototransistor of this invention, the discontinuous PN junctions of the patterned emitter region are arranged in a mesh pattern, distributed within the base region.

In another embodiment of the phototransistor of this invention, the phototransistor further comprises an emitter electrode electrically connected to the patterned emitter region.

In another embodiment of the phototransistor of this invention, the substrate serves as a collector.

In another embodiment of the phototransistor of this invention, the phototransistor further comprises a collector electrode disposed on one side of the substrate.

In another embodiment of the phototransistor of this invention, a width (W_{E}) of the patterned emitter region between the discontinuous PN junctions is greater than 20 micrometers (μm).

In another embodiment of the phototransistor of this invention, a width (W_{B}) of the base region between the discontinuous PN junctions is greater than 6 micrometers (μm).

In another embodiment of the phototransistor of this invention, the ratio of the area of the base region to the total area of the patterned emitter region is not less than 0.09.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a top schematic view of a conventional phototransistor;

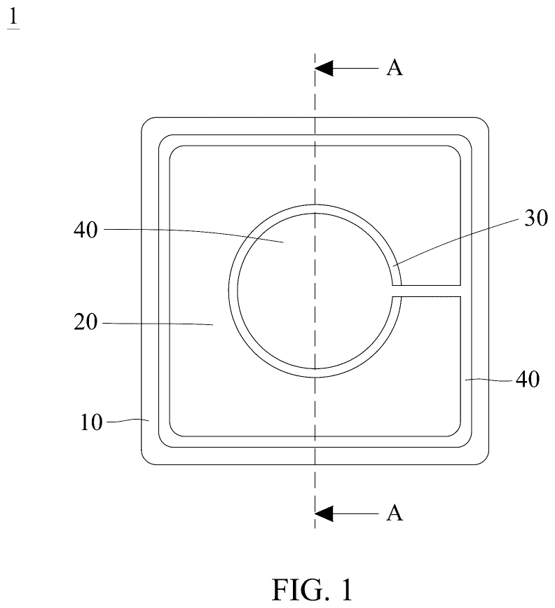

FIG. 2 is a cross-sectional schematic view along the AA line segment of FIG. 1;

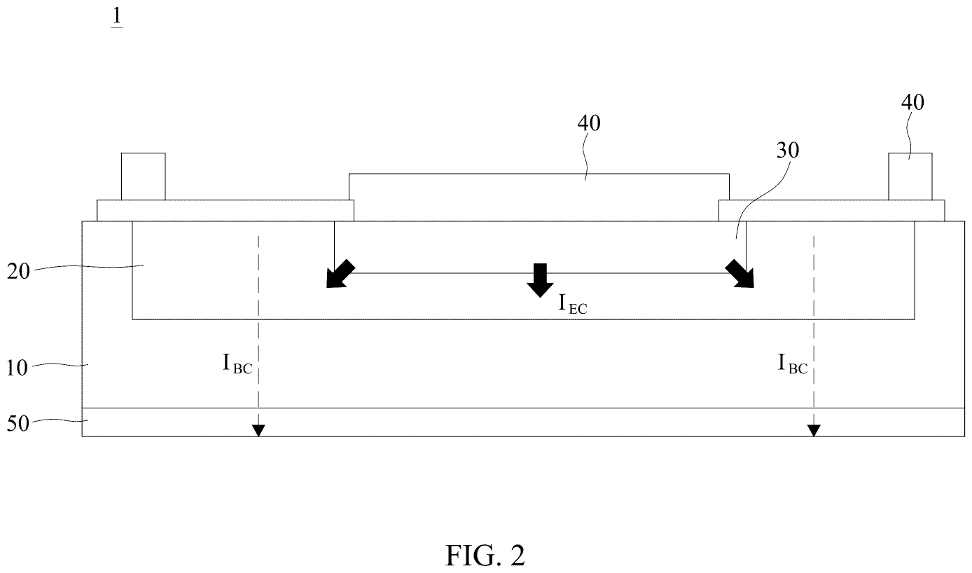

FIG. 3 is a schematic view of the peripheral contour of the emitter region in a conventional phototransistor;

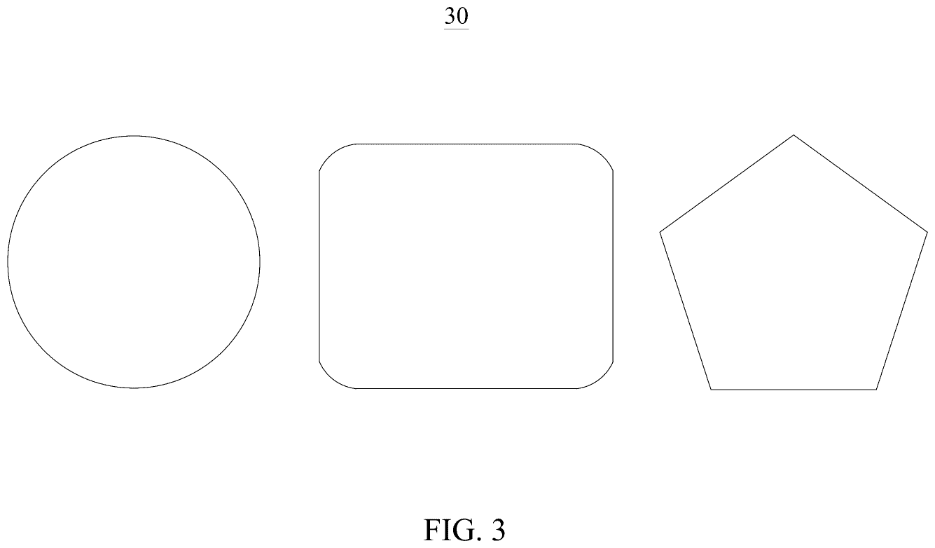

FIG. 4 is a top schematic view of a phototransistor in one embodiment of this invention;

FIG. 5 is a cross-sectional schematic view along the BB line segment of FIG. 4;

FIG. 6 is a schematic view of several grid-pattern peripheral contours of the emitter region in the phototransistor of this invention;

FIG. 7 is a schematic view of several mesh-pattern peripheral contours of the emitter region in the phototransistor of this invention;

FIG. 8 is a schematic view of hFE lifetime test results for different area ratios of the base region to the emitter region in the phototransistor of this invention;

FIG. 9 is a top schematic view of a phototransistor in another embodiment of this invention; and

FIG. 10 is a cross-sectional schematic view along the CC line segment of FIG. 9.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

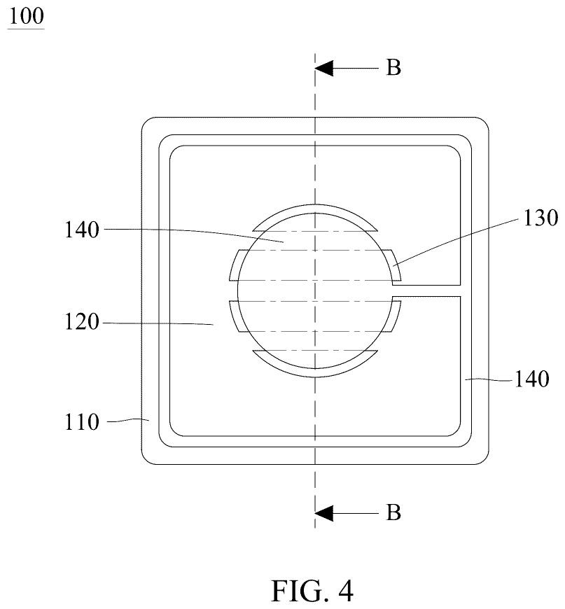

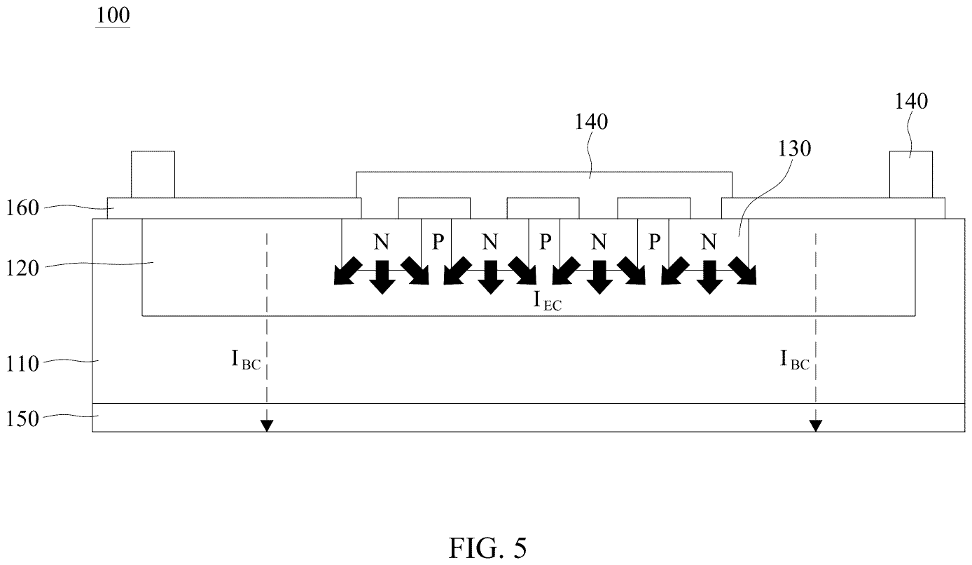

This invention relates to a phototransistor, particularly a phototransistor design capable of increasing photocurrent gain and withstanding high voltage. Please refer to FIG. 4 and FIG. 5 together, where FIG. 4 illustrates a top schematic view of a phototransistor in one embodiment of this invention, and FIG. 5 illustrates a cross-sectional schematic view along the BB line segment of FIG. 4. The phototransistor 100 comprises a substrate 110, a base region 120, an emitter region 130, an emitter electrode 140, and a collector electrode 150.

As shown in FIG. 5, in a specific embodiment, the substrate 110 may be formed as a first conductivity-type compound semiconductor layer using an epitaxial process, such as an N-type gallium arsenide (GaAs) layer, doped with sulfur(S) or silicon (Si) as N-type dopants at a low doping concentration, for example, 10¹⁵ to 10¹⁷/cm³, but not limited thereto. The base region 120 is a second conductivity-type compound semiconductor layer disposed within the substrate 110, for example, a P-type gallium arsenide (GaAs) layer, doped with zinc (Zn) or magnesium (Mg) as P-type dopants at a medium doping concentration, for example, 10¹⁷ to 10¹⁹/cm³. The emitter region 130 is a first conductivity-type compound semiconductor layer disposed in a central area of the light-receiving region 120, for example, an N-type gallium arsenide (GaAs) layer, doped with sulfur(S) or silicon (Si) as N-type dopants at a high doping concentration, for example, 10¹⁸ to 10²⁰/cm³, but not limited thereto.

In this embodiment, the structure of the phototransistor 100 is exemplified as an NPN bipolar junction transistor, where the substrate 110 serves as the collector, the base region 120 serves as the base, and the emitter region 130 serves as the emitter of the phototransistor 100. Additionally, the emitter electrode 140 serves as the electrode for the emitter region, disposed on and electrically connected to the emitter region 130. The collector electrode 150 serves as the electrode for the collector, disposed on one side of the substrate 110 and electrically connected to the substrate 110.

When the surface of the base region 120 is exposed to external light, it can effectively absorb photons to excite electrons, generating electron-hole pairs that are separated under the influence of an electric field to form a current. These electrons and holes are collected between the base region 120 and the substrate 110, forming a base-collector current (I_{BC}). On the other hand, due to the electron flow in the base region 120, the emitter-collector current (I_{EC}) between the emitter region 130 and the substrate 110 increases, resulting in a current gain effect. In another possible embodiment, the structure of the phototransistor 100 of this invention may also be a PNP bipolar junction transistor. Those skilled in the art can readily extend the teachings of this invention to such configurations. The following description will specifically illustrate the technical features of this invention using an NPN bipolar junction transistor as an example.

To address the issue of poor photocurrent gain in conventional phototransistors, one of the technical features of this invention is to provide an innovative emitter structure. As shown in FIG. 4 and FIG. 5, the emitter region 130 has a patterned contour, forming a patterned emitter region. Specifically, unlike the continuous circular or square contours of conventional emitter regions, the patterned emitter region 130 of the phototransistor of this invention comprises a plurality of emitter sub-regions 132, each discontinuous and independently distributed within the base region 120. In this embodiment, since the emitter region 130 is an N-type doped compound semiconductor layer and the base region 120 is a P-type doped compound semiconductor layer, a plurality of discontinuous PN junctions are formed between each emitter sub-region 132 and the base region 120. The total area of these discontinuous PN junctions is significantly larger than the contact area of a conventional emitter region with a continuous contour line, thereby increasing electron injection pathways. As a result, when light illumination activates the device, the base-collector current (I_{BC}) formed between the base region 120 and the substrate 110 leads to an emitter-collector current (I_{EC}) between the emitter region 130 and the substrate 110. Due to the increased contact area between the patterned emitter region 130 and the base region 120, the electron injection pathways between the contact surfaces are significantly increased, thereby enhancing the current gain effect. It should be noted that the device structure of the phototransistor further includes a transparent dielectric layer 160, such as an oxide layer, disposed between the emitter electrode 140 and the base region 120. This layer allows external light to penetrate and be absorbed by the base region 120 while serving as an electrical isolation layer, as shown in FIG. 5. However, for clarity of illustration, the transparent dielectric layer 160 is omitted in the top view of FIG. 4, showing only the relative positions of the base region 120, the emitter region 130, and the emitter electrode 140 to clearly depict their positional relationships.

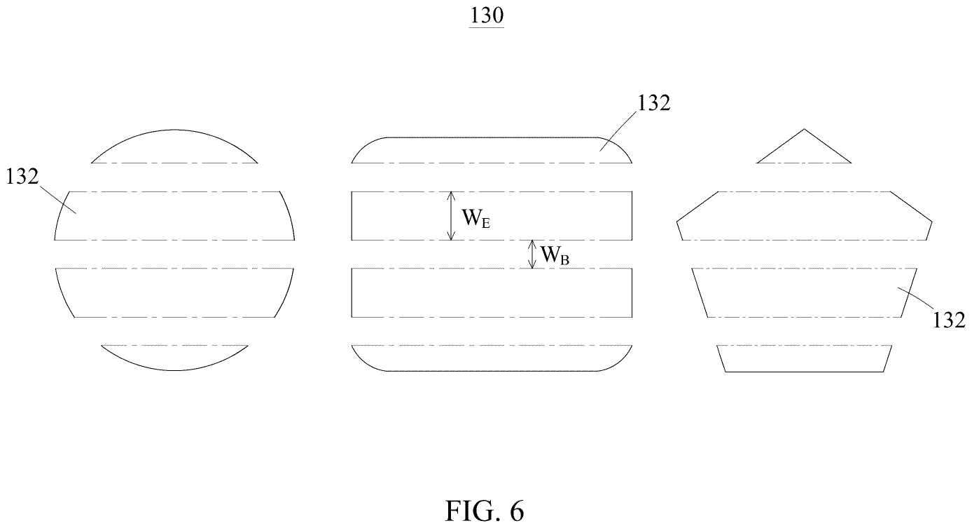

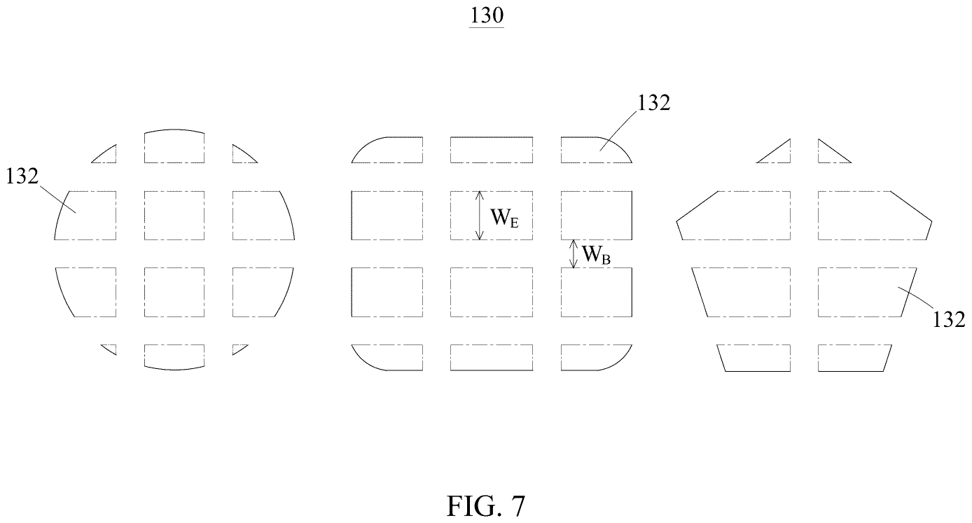

Please refer to FIG. 6 and FIG. 7 together, which illustrate schematic diagrams of various patterned designs of the emitter region 130 in the phototransistor of this invention. FIG. 6 shows the emitter sub-regions 132 of the patterned emitter region 130 arranged in a grid pattern. On the other hand, FIG. 7 shows the emitter sub-regions 132 of the patterned emitter region 130 arranged in a mesh pattern. It should be noted that the patterned contour shapes shown in FIG. 6 and FIG. 7 are for illustrative purposes only and are not intended to limit the present invention. The patterned contour of the emitter region 130 can be adjusted based on device design and current gain requirements. For example, the patterned design of the emitter region 130 may include emitter sub-regions 132 arranged in multiple concentric rings or as multiple independent island-like structures, where the island-like structures may be circular, triangular, or other polygonal shapes. Additionally, since the contact area between the base region 120 and the patterned emitter region 130 is increased in the phototransistor of this invention, the depletion region formed at the PN junction interface between these two regions increases in the absence of external light, thereby suppressing surface leakage current in the phototransistor. Furthermore, as the contact area between the base region 120 and the patterned emitter region 130 increases, the impedance between the base region 120 and the emitter region 130 also increases, thereby enhancing the breakdown voltage of the phototransistor.

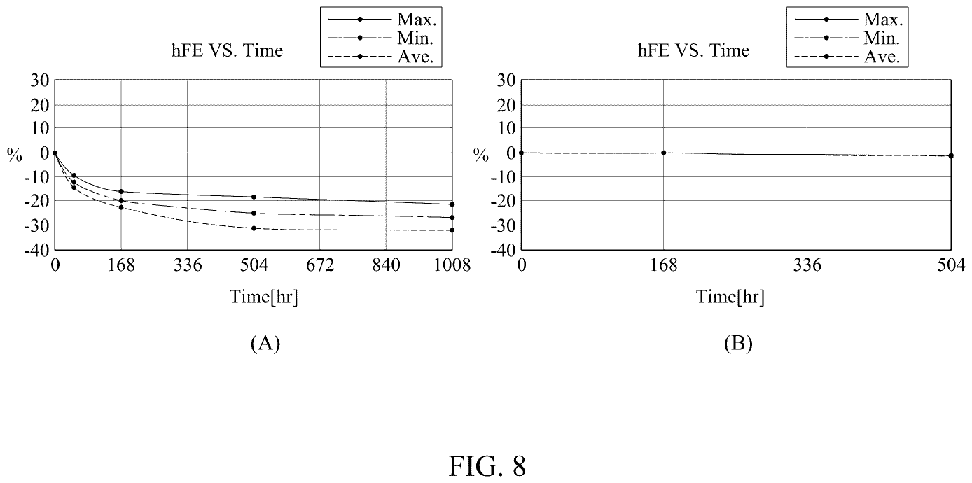

Furthermore, considering saturation current limitations, the following factors must be considered when designing the patterned emitter region 130 of the phototransistor of this invention, as shown in FIG. 6 and FIG. 7: First, the width (W_{E}) of each patterned emitter region 130 (i.e., the width of each emitter sub-region 132 or the width between discontinuous PN junctions) must be greater than 20 micrometers (μm), with 40 micrometers (μm) being optimal. Second, for process considerations, the width (W_{B}) of the base region 120 between adjacent emitter sub-regions 132 (or between discontinuous PN junctions) must be greater than 6 micrometers (μm) to avoid “mutual interference” between adjacent emitter sub-regions, where “mutual interference” includes effects such as crosstalk or crosslinking due to ion diffusion or depletion region overlap. Third, the ratio of the area of the base region 120 to the total area of the emitter sub-regions 132 must be not less than 0.09 to prevent hFE (DC current gain) lifetime degradation due to current crowding. Please refer to FIG. 8, which illustrates hFE lifetime test results for different area ratios of the base region to the emitter region in the phototransistor. Part (A) of FIG. 8 shows that when the area ratio of the base region to the emitter region is less than 0.09, current crowding occurs, leading to hFE lifetime degradation. In contrast, part (B) of FIG. 8 shows that when the area ratio of the base region to the emitter region is not less than (i.e., greater than or equal to) 0.09, no hFE lifetime degradation is observed.

For example, if α is defined as ΔI_{C}/ΔI_{EC}≈I_{C}/I_{EC}, it can be derived that:

$${I}_{C} = α \times {I}_{EC} \qquad ( Equation 1 )$$

where I_{C} represents the collector current, and Δ represents the increment.

According to Kirchhoff's Current Law:

$${I}_{EC} = {I}_{C} + {I}_{B C} \qquad ( Equation 2 )$$

Substituting I_{C} from Equation 1 into Equation 2 yields:

$${I}_{EC} = α \times {I}_{EC} + {I}_{B C} , i . e . , {I}_{B C} = ( 1 - α ) \times {I}_{E C} β , β ( h F E ) = {I}_{C} / {I}_{B C} \qquad ( Equation 3 )$$

$$According to the definition of β , β ( hFE ) = {I}_{C} / {I}_{BC} \qquad ( Equation 4 )$$

Substituting Equation 1 and Equation 3 into Equation 4 yields:

$$β = ( α \times {I}_{E C} ) / ( ( 1 - α ) \times {I}_{EC} ) , ultimately deriving :$$

$$β = α / ( 1 - α )$$

Since α can be approximated as α≈γ×aT, where γ is the ratio of the minority carrier current injected from the emitter region to the base region to the total emitter current (emitter injection efficiency), and aT is the ratio of minority carriers reaching the collector region to those injected into the base region (transport efficiency ratio), it follows that:

$$β \approx γ \times aT / ( 1 - γ \times aT )$$

For example, for a square emitter region design with a size of approximately 125 micrometers (μm), if it is patterned and divided into five segments, the injection efficiency can be increased by approximately 23%. Based on the above equations, without additional costs, the hFE (DC current gain) can be improved by approximately 0.12%.

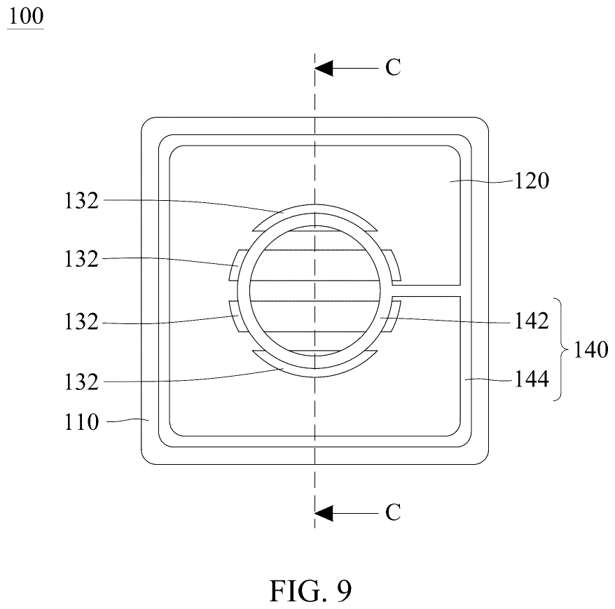

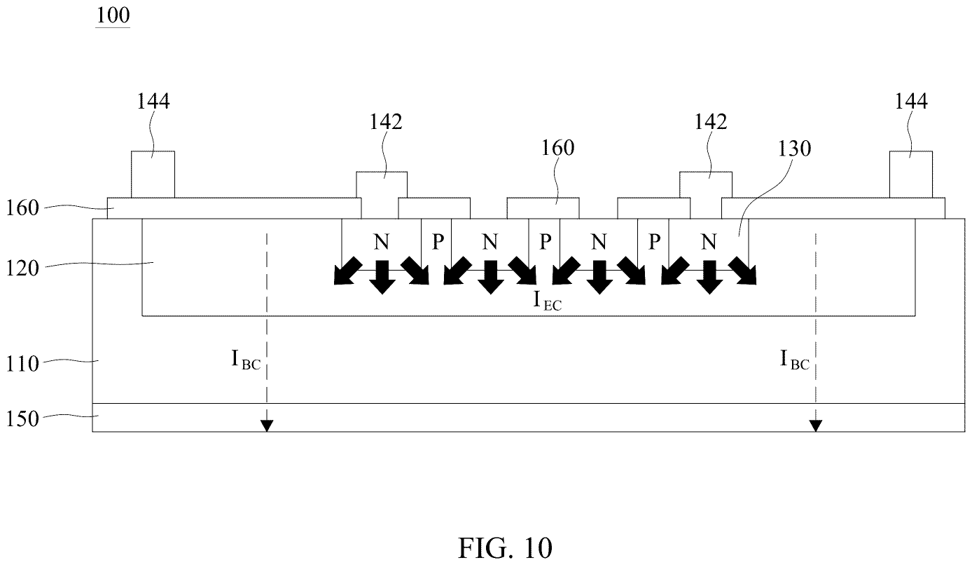

Please refer to FIG. 9 and FIG. 10, where FIG. 9 illustrates a top schematic view of a phototransistor in another embodiment of this invention, and FIG. 10 illustrates a cross-sectional schematic view along the CC line segment of FIG. 9. In this embodiment, the emitter electrode 140 comprises an extension portion 142 and an outer ring portion 144. The extension portion 142 extends from the outer ring portion 144 to the emitter region 130, electrically connecting to the emitter region 130. To increase the light-receiving area of the base region 120 and avoid excessive shading of the light-receiving area of the base region 120 below the emitter region 130, the extension portion 142 above the emitter region 130 is designed as a hollow annular shape, disposed on the edges of the emitter sub-regions 132 of the emitter region 130, and electrically connected to each emitter sub-region 132. The hollow annular extension portion 142 substantially reduces shading of the light-receiving base region below the emitter region, thereby increasing the base-collector current (I_{BC}). Combined with the current gain enhancement effect of the patterned emitter region, the synergistic effect of both achieves the optimal photocurrent gain. Notably, this improvement in current gain not only enhances the performance of optical components but can also be achieved without increasing manufacturing costs, meeting the requirements for optimized device design.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A phototransistor, comprising:
a first conductivity-type substrate;
a second conductivity-type base region disposed within the first conductivity-type substrate; and
a first conductivity-type patterned emitter region comprising a plurality of emitter sub-regions, each independently disposed within the second conductivity-type base region to increase electron injection pathways.

2. The phototransistor of claim 1, wherein the emitter sub-regions of the first conductivity-type patterned emitter region are arranged in a grid pattern, distributed within the second conductivity-type base region.

3. The phototransistor of claim 1, wherein the emitter sub-regions of the first conductivity-type patterned emitter region are arranged in a mesh pattern, distributed within the second conductivity-type base region.

4. The phototransistor of claim 1, further comprising an emitter electrode electrically connected to the first conductivity-type patterned emitter region.

5. The phototransistor of claim 4, wherein the emitter electrode comprises an extension portion and an outer ring portion, the outer ring portion being disposed on an edge of the second conductivity-type base region, and the extension portion extending from the outer ring portion to the first conductivity-type patterned emitter region, electrically connecting to each of the emitter sub-regions of the first conductivity-type patterned emitter region.

6. The phototransistor of claim 5, wherein the extension portion has a hollow annular shape, disposed on an edge of the first conductivity-type patterned emitter region.

7. The phototransistor of claim 1, wherein the first conductivity-type substrate serves as a collector.

8. The phototransistor of claim 7, further comprising a collector electrode disposed on one side of the first conductivity-type substrate.

9. The phototransistor of claim 1, wherein a width (W_{E}) of each of the emitter sub-regions is greater than 20 micrometers (μm).

10. The phototransistor of claim 1, wherein a width (W_{B}) of the second conductivity-type base region between each of the adjacent emitter sub-regions is greater than 6 micrometers (μm).

11. The phototransistor of claim 1, wherein the ratio of the area of the second conductivity-type base region to the total area of the first conductivity-type patterned emitter region is not less than 0.09.

12. A phototransistor, comprising:
a substrate;
a base region disposed within the substrate; and
a patterned emitter region having a plurality of discontinuous PN junctions with the base region to increase electron injection pathways.

13. The phototransistor of claim 12, wherein the discontinuous PN junctions of the patterned emitter region are arranged in a grid pattern, distributed within the base region.

14. The phototransistor of claim 12, wherein the discontinuous PN junctions of the patterned emitter region are arranged in a mesh pattern, distributed within the base region.

15. The phototransistor of claim 12, further comprising an emitter electrode electrically connected to the patterned emitter region.

16. The phototransistor of claim 12, wherein the substrate serves as a collector.

17. The phototransistor of claim 16, further comprising a collector electrode disposed on one side of the substrate.

18. The phototransistor of claim 12, wherein a width (W_{E}) of the patterned emitter region between the discontinuous PN junctions is greater than 20 micrometers (μm).

19. The phototransistor of claim 12, wherein a width (W_{B}) of the base region between the discontinuous PN junctions is greater than 6 micrometers (μm).

20. The phototransistor of claim 12, wherein the ratio of the area of the base region to the total area of the patterned emitter region is not less than 0.09.
